(19) United States
(12) Patent Application Publication
(10) Pub. No.: US 2010/0151636 A1
(43) Pub. Date: Jun. 17, 2010

(54) Methods to make fine patterns by exploiting difference of threshold laser fluence of materials and tft fabrication methods using the same

(76) Inventors: Dong-Youn SHIN, Daejeon (KR); Taik-Min LEE, Daejeon (KR); Dong-Soo KIM, Daejeon (KR)

Correspondence Address: CLARK & BRODY, 1700 Diagonal Road, Suite 510, Alexandria, VA, 22314, US

(21) Appl. No.: 12/453,071

(22) Filed: Apr. 29, 2009

(30) Foreign Application Priority Data
Dec. 11, 2008 (KR) 10-2008-0126005

(51) Int. Cl. H01L 21/336; H01L 21/26; H01L 21/30; H01L 21/28

(52) U.S. Cl. 438/158; 438/795; 438/759; 438/589; 257/E21.328; 257/E21.211; 257/E21.19; 257/E21.411

(57) ABSTRACT

Disclosed are methods of making fine patterns by exploiting difference in threshold laser fluence of materials and a thin film transistor (TFT) fabrication methods using the same, and more particularly, to a method of forming a fine pattern and a method of fabricating a TFT through the same method, in which a plurality of layers different in threshold laser fluence are stacked and then exposed to a laser so that a layer having a low threshold laser fluence can be selectively removed, thereby making fine patterns precisely and forming a cavity of a gate electrode precisely and easily.

### CROSS-REFERENCE TO RELATED APPLICATION

This application claims the benefit of Korean Patent Application No. 2008-0126005, filed Dec. 11, 2008, the disclosure of which is hereby incorporated herein by reference in its entirety.

### BACKGROUND OF THE INVENTION

1. Field of the Invention

The present invention relates to methods of making fine patterns by exploiting difference in threshold laser fluence of materials and a thin film transistor (TFT) fabrication methods using the same, and more particularly, to a method of forming a fine pattern and a method of fabricating a TFT through the same method, in which a plurality of layers different in threshold laser fluence are stacked and then exposed to a laser so that a layer having a low threshold laser fluence can be selectively removed, thereby making fine patterns precisely and forming a cavity of a gate electrode precisely and easily.

2. Description of the Related Art

In general, a thin film transistor (TFT) is a kind of field effect transistor (FET), which basically has three terminals of a gate electrode, a source electrode and a drain electrode.

In a TFT as shown in FIG. 1, a source electrode S and a drain electrode D spaced apart from each other are formed on a substrate T, and a gate electrode G is formed above them. The spaced part between the source electrode S and the drain electrode D is used as a gate cavity filled with a semiconductor material and a dielectric material.

If there is a portion where the source electrode S or the drain electrode D is overlapped with the gate electrode G, this portion causes a parasitic capacity, thereby deteriorating the electrical characteristics of the TFT. Thus, it is required that the gate electrode G has to be precisely formed not to overlap with the source electrode S or the drain electrode D.

To this end, a surface energy patterning method and a self aligned imprint lithography method have been employed conventionally. However, the surface energy patterning method has a problem of complicated processes since it depends on an additional free patterning method that differentiates surface free energy of an area where the gate electrode is positioned after forming the source electrode and the drain electrode. Further, the self aligned imprint lithography method has a problem of excessive material waste since expensive materials are removed by etching.

### SUMMARY OF THE INVENTION

The present invention is conceived from the foregoing and/or other problems, and an aspect of the present invention is to provide a method of forming a method, in which a plurality of layers different in threshold laser fluence are stacked and then exposed to a laser so that a layer having a low threshold laser fluence can be selectively removed, thereby making fine patterns precisely and forming a cavity of a gate electrode precisely and easily.

Additional aspects and advantages of the present invention will be set forth in part in the description which follows and, in part, will be obvious from the description, or may be learned by practice of the invention based on means from and combination of claims.

The foregoing and/or other aspects of the present invention may be achieved by providing a method of making fine patterns by exploiting difference in threshold laser fluence of materials, the method including: stacking a lower layer on a substrate; stacking an upper layer having a threshold laser fluence higher than a threshold layer fluence of the lower layer on the lower layer and the substrate; and forming a cavity by emitting a laser toward the lower layer and removing the lower layer and the upper layer stacked on the lower layer, in which a certain region is selectively removed by exploiting difference in threshold laser fluence of materials, and then ink is filled in and self-aligned in the removed region, thereby making the fine patterns.

Another aspect of the present invention may be achieved by providing a method of making fine patterns by exploiting difference in threshold laser fluence of materials, the method including: stacking a lower layer on a substrate; preparing a plurality of partitions spaced apart from each other by patterning the lower layer; stacking an upper layer having a threshold laser fluence higher than a threshold layer fluence of the lower layer on the partition and the substrate; forming a cavity by emitting a laser toward the partition and removing the partition and the upper layer stacked on the partition, filling the cavity with ink; and exploiting self-alignment of the ink.

Still another aspect of the present invention may be achieved by providing a method of fabricating a thin film transistor (TFT) by exploiting difference in threshold laser fluence of materials, the method comprising: stacking a lower layer on a substrate; preparing a plurality of partitions spaced apart from each other by patterning the lower layer; filling conductive ink used as a source electrode and a drain electrode of the TFT between the partitions; stacking a hydrophobic insulation layer having a threshold laser fluence higher than a threshold laser fluence of the partition on the conductive ink and the partition; forming a cavity for a gate electrode by emitting a laser toward the partitions and removing the partitions and the hydrophobic insulation layer stacked on the partitions; and filling the cavity with a semiconductor material, a dielectric material and conductive ink used as the gate electrode.

### BRIEF DESCRIPTION OF THE DRAWINGS

These and/or other aspects and advantages of the present invention will become apparent and more readily appreciated from the following description of the embodiments, taken in conjunction with the accompanying drawings of which:

FIG. 1 is a schematic view of a conventional structure of a thin film transistor (TFT);

FIGS. 2 to 4 are schematic views of a fine patterning method according to an exemplary embodiment of the present invention; and

FIGS. 5 to 9 are schematic views of fabricating a TFT through the fine patterning method according to an exemplary embodiment of the present invention.

### DETAILED DESCRIPTION OF THE INVENTION

The present invention relates to methods of making fine patterns by exploiting difference in threshold laser fluence of materials and a thin film transistor (TFT) fabrication methods using the same. First, methods of making fine patterns by exploiting difference in threshold laser fluence of materials will be described.

### Embodiment 1

A method S100 of making fine patterns includes a step S110 of stacking a lower layer 110 on a substrate T, a step S120 of stacking an upper layer 120 having a threshold laser fluence higher than that of the lower layer 110 on the lower layer 110 and the substrate T, and a step S130 of forming a cavity C by emitting a laser toward the lower layer 110 and removing the lower layer 110 and the upper layer 120 stacked on the lower layer 110.

The threshold laser fluence indicates a threshold value at which the lower layer 110 or the upper layer 120 absorbs the laser and is broken down or volatilized to be removed. In general, materials are different in the threshold value to be decomposed by absorbing the laser. In this embodiment using such properties, a fine pattern is made on the principle that the layer having a lower threshold laser fluence is first broken out if a plurality of layers different in the threshold laser fluence are stacked and then exposed to the laser.

At this time, the threshold laser fluence may be evaluated in various respects. For example, in light of energy absorbed in the plurality of layers due to the laser exposure, there may be a layer decomposed by relatively low energy absorption, and this layer can be evaluated as it has a low threshold laser fluence. Further, the plurality of layers may be different in a certain wavelength range of the laser to be absorbed, and a layer that absorbs the laser of the certain wavelength range well and is first decomposed can be evaluated as it has a low threshold laser fluence. In other words, the present invention defines that the layer first decomposed by the laser exposure has a threshold laser fluence lower than that of other layers in light of the laser energy or the certain wavelength range.

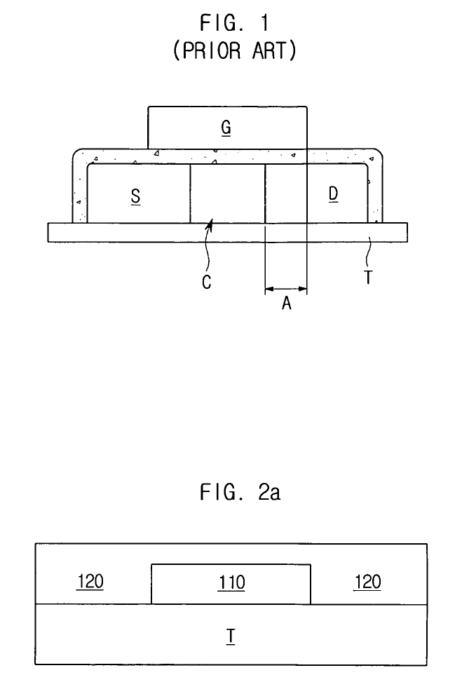

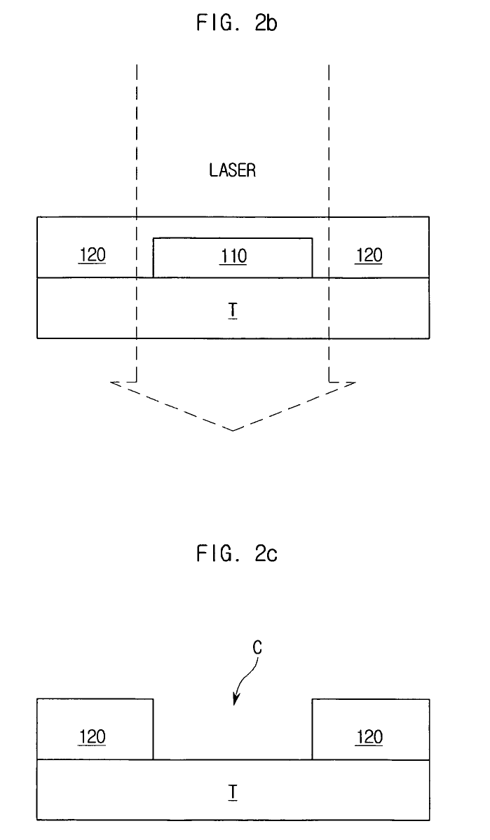

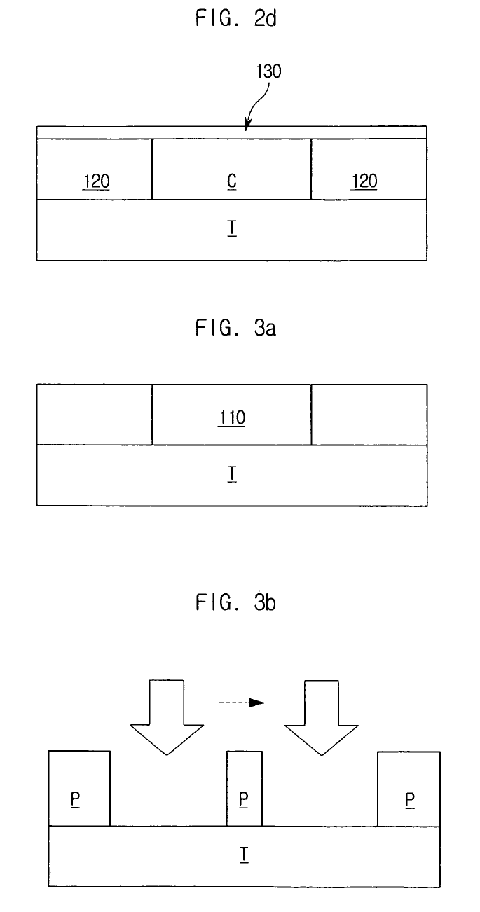

Below, the embodiment 1 will be described in more detail with reference to FIGS. 2a to 2d.

In this embodiment, as shown in FIG. 2a, the step S120 of covering top, left and right sides of the lower layer 110 with the upper layer 120 is carried out after performing the step S110 of stacking the lower layer 110 on the substrate T. Here, the threshold laser fluence of the upper layer 120 is higher than that of the lower layer 110.

As methods of stacking the lower layer 110, there are a spin coating method; a photolithography method; an inkjet method of jetting out a material; a screen printing method using a stencil mask (or called a screen) and a squeezer to form a pattern on a substrate; an electrostatic printing method using a material having a static charge to stack the material; an offset printing method of transferring a material to a rubber sheet called a blanket and then transferring the functional material on the blanket to the substrate again; a gravure printing method engraving a gravure image, transferring the functional material on the blanket and then indirectly printing it onto a substrate like the offset printing method; a flexo-printing method using a flexible resin or a rubber plate as a kind of relief printing; a printing method using a soft mold; a slit coating method using a slit coater to stack the functional material; etc.

Further, there may be used a drop-on-demand method for dropping ink on only a demanding region. The drop-on-demand includes a thermal method employing a heater as a driving source to drop the ink, and a piezo method pushing the ink out through a piezo element. Also, there may be used a continuous ink jet method that continuously jets the ink and deviates and stacks the ink in a need time.

With the methods as described above, the lower layer 110 is staked and then the step S120 of stacking the upper layer 120 on the lower layer 110 and the substrate T is performed. Of course, the upper layer 120 can be stacked by the foregoing various methods. In respect of staking the upper layer 120, the thinner a region of the upper layer 120 stacked on the lower layer 110, the better, which will be described later.

After performing this step, the laser is emitted toward the lower layer 110, and the lower layer 110 and the upper layer 120 stacked on the lower layer 110 are removed to form the cavity C, i.e., the step S130 is performed.

As described above, the threshold laser fluence of the lower layer 110 is lower than that of the upper layer 120. Thus, the lower layer 110 is first removed by the emitted laser, and then the region of the upper layer 120 stacked on the lower layer 110 is removed together with the lower layer 110. At this time, the thinner the upper layer 120 covering the lower layer 110, the better to remove the upper layer 120 stacked on the lower layer 110 together with the lower layer 110.

In this embodiment, the laser for removing the lower layer 110 has a wavelength of 532 nm, and a focused laser beam has a diameter of about 80 μm and has an energy per unit area of about 130 mJ/cm². That is, the threshold laser fluence of the lower layer 110 means the energy per unit area of about 130 mJ/cm² in the laser having a wavelength of 532 nm. The wavelength and the energy per unit area of the laser may vary depending on the material of the lower layer 110.

Meanwhile, the lower layer 110 and the upper layer stacked on the lower layer 110 are removed to thereby form the cavity C. As described above, since the cavity C is formed when the laser is emitted toward the lower layer 110, it is possible to form a fine pattern having a line width required as wide as the line width of the lower layer 110 even though of the laser beam having a diameter IS larger than the width of the cavity C is used, thereby forming the fine pattern precisely.

The cavity C is filled with ink, in which the upper layer 120 may have hydrophobic properties, but the substrate T meeting the cavity C may have hydrophilic properties, thereby allowing the filled ink to be self-aligned. This will be described again in the following embodiment 2.

The lower layer 110 is a solid or gel state at room temperature, but not limited as long as it can be evaporated or decomposed by a condensed energy beam. As an example of a high molecular substance decomposable by the laser or the like, there may be one selected from a group consisting of polypropylene carbonate, poly(alphamethylstyrene), polymethylmethacrylate, polybutylmetacrylate, cellulose acetate, nitro cellulose, polyvinyl chloride, poly(vinyl chloride), poly acetal, polyvinylidene chloride, polyurethane, polyester, polyorthoester, poly acrylonitrile, modified acrylonitrile, maleic resin, copolymer of the same, and a mixture of the high molecules, but not limited thereto.

Also, as an example of a substance gasified/evaporated by itself due to the laser or the like or gasified/evaporated by additives absorbing a certain wavelength range, there may be one selected from a group consisting of acetamide, 2-amino pyridine, 2-amino-3-methylpyridine, 2-amino-6-methylpyridine, 2-chloro pyridine, 3-bromo pyridine, 3-cyano pyridine, 4-cyano pyridine, 1,3-di-(4-piperidyl)propane, diethanolamine, di-isopropanolamine, 2-ethanol piperidine, ethylene diamine tetra acetic acid, isobutanolamine, N-methyl acetamide, p-toluidine, triisopropanolamine, N-vinyl-2-caprolactam, maleic acid, pivalic acid, trichloroacetic acid, behenyl alcohol, 2,3-butanediol, butanediol, cyclohexanol, 2,2-dimethylpropanol, 1,6-hexanediol, 1-heptanol, bornyl acetate, cetyl acetate, ethylene carbonate, methyl behenate, diphenyleter, n-hexyl eter, 1,3,4-trioxane, 3-ethoxy-1-propanol, benzophenone, p-methylacetophenone, phenylacetone, catechol, p-cresol, hydroquinone, 4-ethylphenol, 2-methoxyphenol, phenol, thymol, 2,3-xylenol and 2,5-xylenol. Further, the substance includes organic or inorganic materials that can be easily removed by the laser within the scope of the present invention.

Meanwhile, the lower layer 110 may be a single layer made of a single material or a multi layer made of plural materials.

Likewise, the upper layer 120 may include the foregoing material, and may include any material as long as it has a threshold laser fluence higher than that of the lower layer 110 ad described above.

Further, as shown in FIG. 2d, a passivation layer 130 may be added to the top side of the cavity C and the upper layer 120.

### Embodiment 2

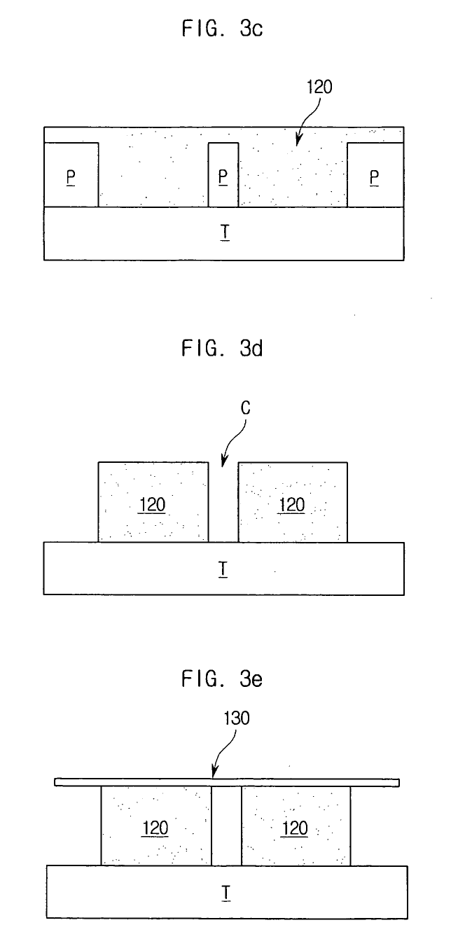

As shown in FIGS. 3a to 3e, a method S200 of making fine patterns in this embodiment includes a step S210 of stacking a lower layer 110 on a substrate T, a step S220 of preparing a plurality of partitions P spaced apart from each other by patterning the lower layer 110, a step S230 of stacking an upper layer 120 having a threshold laser fluence higher than that of the lower layer 110 on the partitions P and the substrate T, and a step S240 of forming a cavity C by emitting a laser toward the partitions P and removing the partitions P and the upper layer 120 stacked on the partitions P.

In this embodiment, the same numerals refer to the upper and lower layers of the embodiment 1 described above, which means that the upper and lower layers can be stacked by the foregoing materials and methods.

The step S210 of stacking the lower layer 110 is equal to that of the embodiment 1.

After performing the step S210, the step S220 of patterning the lower layer 110 to prepare the plurality of partitions P spaced apart from each other is performed.

In the step S220, the laser is emitted to a certain region of the lower layer 110 so as to remove the lower layer 110, and then moves to be emitted to another region so as to remove the lower layer 110. As another method for patterning the lower layer 110, for example, a photolithography method may be used, and only the separated lower layer 110 and the partition P may be stacked in the beginning of stacking the lower layer 110. Here, since the partition P is a region to be used as a gate cavity C, this embodiment employed the foregoing method using a laser suited for enhancing the precision.

After forming the partitions P in the step S220, the step S230 of stacking the upper layer 120 having a threshold laser fluence higher than that of the lower layer 110 on the partitions P and the substrate T is carried out.

Then, the step S240 of forming the cavity C by emitting the laser toward the partitions P and removing the partitions P and the upper layer 120 stacked on the partitions P is performed. The partition P has a threshold laser fluence lower than that of the upper layer 120 since it is a part of the lower layer 110. Thus, when the laser is emitted toward the partitions P, the partitions P are removed earlier than the upper layer 120, thereby removing the upper layer 120 stacked on the partition P. To this end, the thinner the upper layer 120 stacked on the partitions P, the better.

In result, the cavity C is formed to thereby form fine patterns precisely.

At this time, it is possible to form a thin film transistor (TFT, to be described later) by filling the cavity C with ink, particularly, conductive ink, in which the upper layer 120 may have hydrophobic properties, but a top surface of the substrate T in a region to be filled with the ink, i.e., the substrate T meeting the cavity C may have hydrophilic properties, thereby allowing the filled ink to be self-aligned. If the upper layer 120 has the hydrophobic properties but the substrate T in the region to be filled with the ink has the hydrophilic properties, the ink flows toward not the upper layer 120 but the substrate T, so that the ink can be precisely filled in the cavity C by the self aligning.

The upper layer 120 may become hydrophobic by using a hydrophobic material, adding a hydrophobic coating layer, a plasma process of CF₄, or adding a hydrophobic material, etc. Thus, the upper layer 120 can have the hydrophobic properties.

After filling the cavity C with the ink, a passivation layer 130 may be stacked on the cavity C and the upper layer 120, thereby protecting processed results after forming the fine patterns.

Meanwhile, the top side of the substrate T, i.e., the top side of the upper layer 120 may be illuminated by the laser, and the bottom side of the substrate T may be illuminated by the laser if the substrate T is transparent.

### Embodiment 3

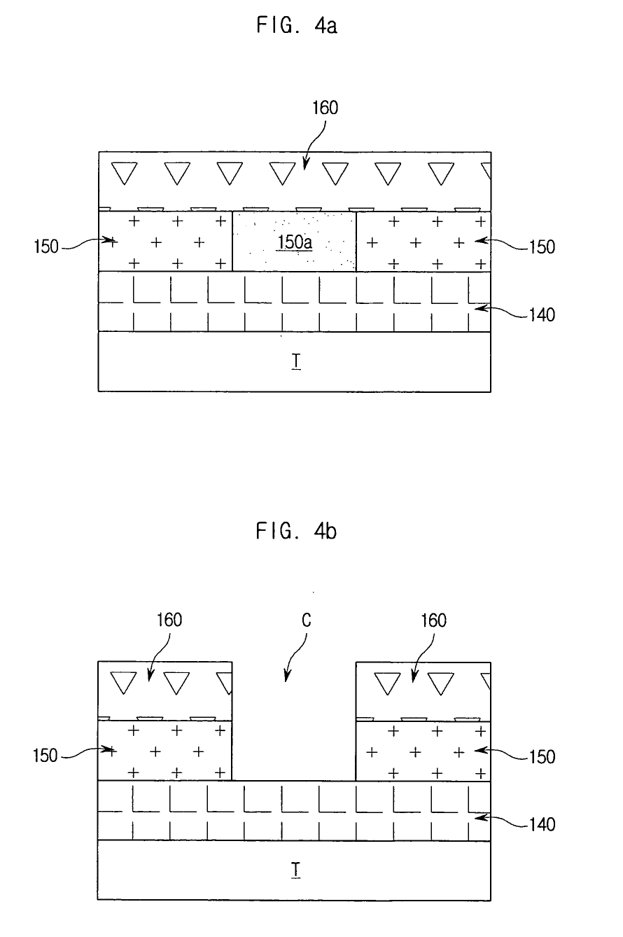

As shown in FIGS. 4a to 4b, a method S300 of making fine patterns in this embodiment includes a step S310 of stacking a lower layer 140 on a substrate T; a step S320 of stacking a first intermediate layer 150a having a threshold laser fluence lower than that of the lower layer 140 on the lower layer 140 and stacking a second intermediate layer 150 having a threshold laser fluence higher than that of the first intermediate layer 150a on the top side of the lower layer 140 and the lateral sides of the first intermediate layer 150a; a step S330 of stacking an upper layer 160 having a threshold laser fluence higher than that of the first intermediate layer 150a on the first and second intermediate layers 150a and 150; and a step S340 of forming a cavity C by emitting a laser toward the first intermediate layer 150a and removing the first intermediate layer 150a and the upper layer 160 stacked on the first intermediate layer 150a.

In this embodiment, three layers 140, 150 and 160 are stacked as shown in FIG. 4a.

Here, the threshold laser fluence of the first intermediate layer 150a interposed between the upper layer 160 and the lower layer 140 is lower than those of the adjacent layers.

This can be achieved by a method of first stacking the first intermediate layer 150 having a low threshold laser fluence after forming the lower layer 140; staking the intermediate layer 150 on the left and right sides of the first intermediate layer 150a; and stacking the upper layer 160.

Further, this can be achieved by a method of stacking the intermediate layer 150 on the entire area of the lower layer 140; removing a part corresponding to the first intermediate layer 150a through laser exposure; stacking the first intermediate layer 150a having a low threshold laser fluence as described above; and stacking the upper layer 160.

After performing the step S320, if the laser is emitted toward the first intermediate layer 150a, the first intermediate layer 150a and the upper layer 160 stacked on the first intermediate layer 150a are removed thereby forming the cavity C as shown in FIG. 4b.

Accordingly, the methods of making the fine patterns using the threshold laser fluence were described above, and method of fabricating the TFT using the same will be described below.

### Embodiment 4

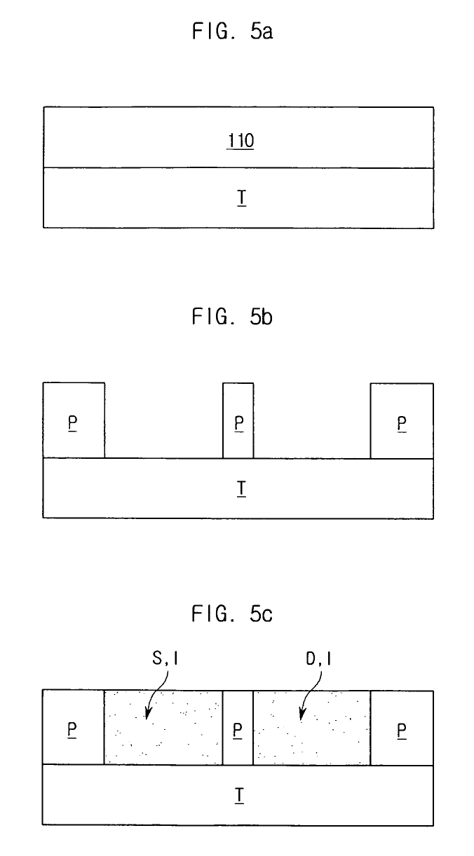

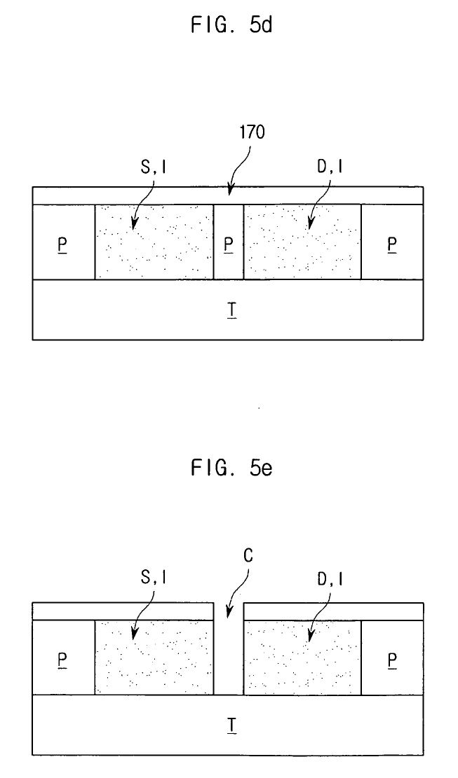

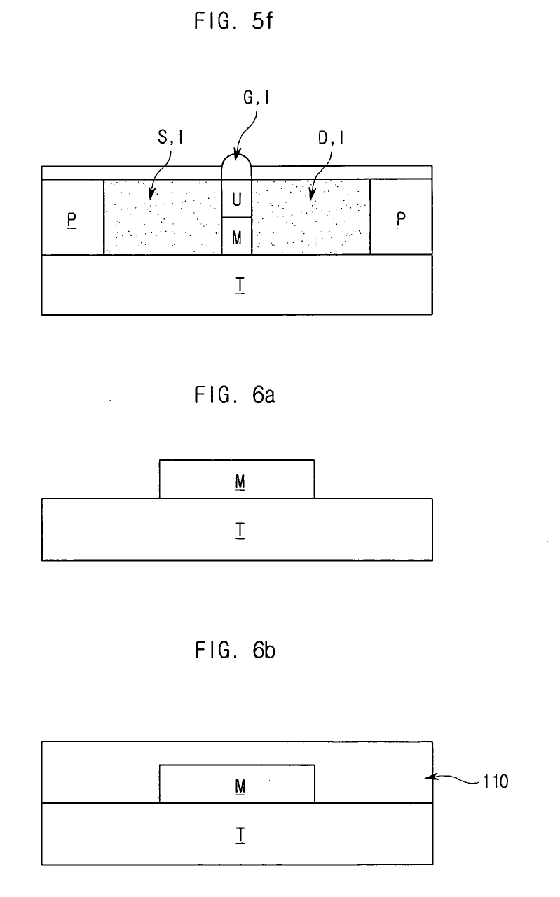

As shown in FIGS. 5a to 5e, a method S400 of fabricating a thin film transistor (TFT) in this embodiment includes a step S410 of stacking a lower layer 110 on a substrate T; a step S420 of preparing a plurality of partitions P spaced apart from each other by patterning the lower layer 110; a step S430 of filling conductive ink I used as a source electrode S and a drain electrode D of the TFT between the partitions P; a step S440 of stacking a hydrophobic insulation layer 170 having a threshold laser fluence higher than that of the partition P on the conductive ink and the partition P; a step S450 of forming a cavity C for a gate electrode G by emitting a laser toward the partitions P and removing the partitions P and the hydrophobic insulation layer 170 stacked on the partitions P; and a step S460 of filling the cavity C with a semiconductor material M, a dielectric material U and conductive ink I used as the gate electrode G.

Referring to FIGS. 5a and 5b, the step S410 of forming the lower layer 110 on the substrate T and the step S420 of preparing the partitions P are equal 20 to those of the foregoing embodiments, and thus repetitive descriptions thereof will be avoided.

As shown in FIG. 5c, the step S430 of filling the conductive ink I between the partitions P is performed. Here, the conductive ink I is used as the source electrode S and the drain electrode D of the TFT. In FIG. 5c, reference alphabets S, I and D, I refer to the source electrode and the drain electrode, respectively, which means that the conductive ink is used as the source electrode and the drain electrode.

After performing the step S430, the step S440 of stacking the hydrophobic insulation layer 170 having the threshold laser fluence higher than that of the partition P on the conductive ink I and the partition P is performed.

After performing the step S440, the step S450 of forming the cavity C for the gate electrode G. by emitting a laser toward the partitions P and removing the partitions P and the hydrophobic insulation layer 170 stacked on the partitions P is carried out. Through the laser exposure, the partition P is first removed since the partition P has a threshold laser fluence lower than that of the hydrophobic insulation layer 170, and a part of the hydrophobic insulation layer 170 stacked on the partition P is removed along with the removal of the partition P, thereby forming the cavity C like those of the foregoing descriptions. Of course, it will be appreciated that the conductive ink I has to have the threshold laser fluence higher than that of the partition P so as not to be removed when the partition P is removed.

After performing the step S450, the step S460 of filling the cavity C with the semiconductor material M, the dielectric material U and the conductive ink I used as the gate electrode G is implemented to thereby fabricate the TFF.

At this time, the source electrode S and the drain electrode D bisected by the cavity C have the hydrophobic properties, so that the semiconductor material M, the dielectric material U and the conductive ink I used as the gate electrode G can be filled in the cavity C as being self-aligned. If the source electrode S and the drain electrode D have the hydrophobic properties, the conductive ink I used as the gate electrode G flows toward not the source electrode S and the drain electrode D but the cavity C.

To give the source electrode S and the drain electrode D the hydrophobic properties, hydrophobic additives may be added to the conductive ink or the surfaces of the source electrode S and the drain electrode D may undergo a plasma process of CF₄, etc. Thus, if the hydrophobic properties are given to the source electrode S and the drain electrode D, the hydrophobic insulation layer 170 is not indispensably needed.

Due to difference in surface energy, the semiconductor, the dielectric and the ink for the gate electrode G are precisely stacked in the cavity C, thereby preventing parasitic capacity in contrast to the conventional cases.

The conductive ink I may include one or two or more functional materials selected from a group consisting of conductive organic materials such as poly(3,4-ethylenedioxylthiophene)(PEDOT)-poly(4-styrensulfonate)(PSS); nano-particle conductive inorganic materials such as copper, aluminum, etc.; a precursor of a conductive material such as an organic metal compound; organic/inorganic fluorescent of phosphorescent materials used in an electroluminescent device; an insulator or dielectric; organic/inorganic semiconductor materials or their precursors. Further, the conductive ink I may include organic silver.

### Embodiment 5

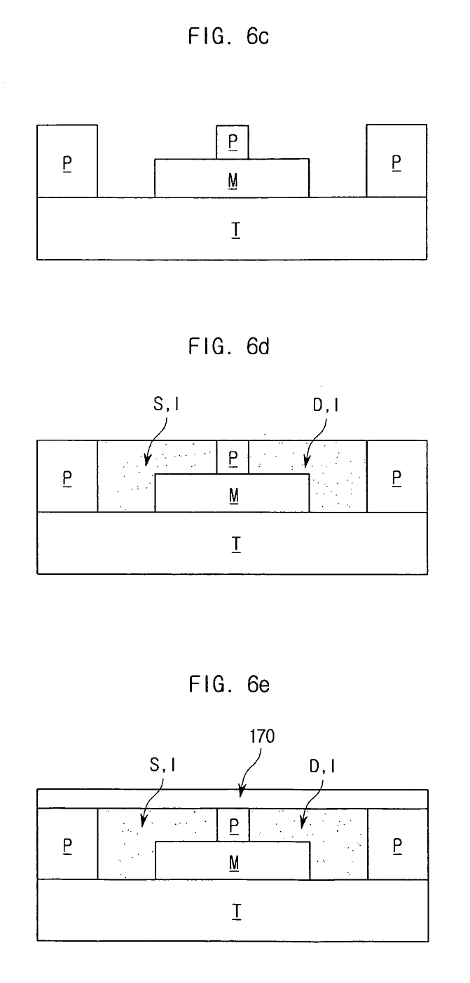

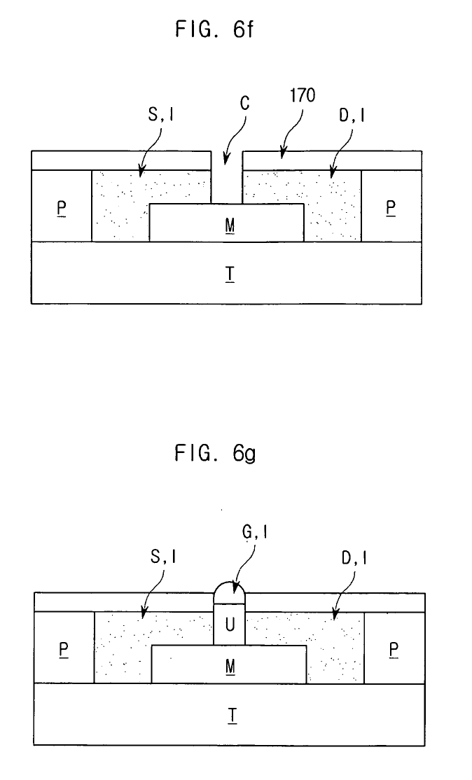

As shown in FIGS. 6a to 6g, a method S500 of fabricating a thin film transistor (TFT) in this embodiment includes a step S510 of stacking a semiconductor material M on a substrate T; a step S520 of stacking a lower layer 110 on the substrate T and the semiconductor material M; a step S530 of preparing a plurality of partitions P spaced apart from each other by patterning the lower layer 110, in which at least one partition P is provided on the semiconductor material M; a step S540 of filling conductive ink I used as a source electrode S and a drain electrode D of the TFT between the partition P on the semiconductor material M and the neighboring partition P; a step S550 of stacking a hydrophobic insulation layer 170 having a threshold laser fluence higher than that of the partition P on the conductive ink I and the partition P; a step S560 of forming a cavity C for a gate electrode G exposing the semiconductor material M by emitting a laser toward the partition P on the semiconductor material M and removing the partition P on the semiconductor material M and the hydrophobic insulation layer 170 stacked on the partition P on the semiconductor material M; and a step S570 of filling a dielectric material U and the conductive ink I used as the gate electrode G on the semiconductor material M exposed through the cavity C.

As shown in FIG. 6a, the step S510 of stacking the semiconductor material M on the substrate T is performed. Then, the step S520 of stacking the lower layer 110 on the substrate T and the semiconductor material T is performed. Then, the step S530 is performed to prepare the plurality of partitions P spaced apart from each other by patterning the lower layer 110, in which at least one partition P is provided on the semiconductor material M. This embodiment is similar to the foregoing embodiment 4, but different in that at least one partition P is formed on the semiconductor material M.

After performing the step S530, as shown in FIGS. 6d and 6e, the step S540 is performed to fill the conductive ink I used as the source electrode S and the drain electrode D of the TFT between the partition P on the semiconductor material M and the neighboring partition P; and the step S550 is performed to stack the hydrophobic insulation layer 170 having a threshold laser fluence higher than that of the partition P on the conductive ink I and the partition P, which are equal to those of the embodiment 4.

After performing the step S550, as shown in FIG. 6f, the step S560 is carried out to form the cavity C for the gate electrode G exposing the semiconductor material M by emitting the laser toward the partition P on the semiconductor material M and selectively removing the partition P on the semiconductor material M and the hydrophobic insulation layer 170 stacked on the partition P on the semiconductor material M. Of course, it will be appreciated that the semiconductor material M has to have the threshold laser fluence higher than that of the partition P so as not to be removed by the laser.

After performing the step S560, as shown in FIG. 6g, the step S570 of filling the dielectric material U and the conductive ink I used as the gate electrode G on the semiconductor material M exposed through the cavity C, which is similar to that of the foregoing embodiment 4.

Meanwhile, the TFT is precisely fabricated through self-aligning by giving the hydrophobic properties to the source electrode S and the drain electrode D like that of the foregoing embodiment, and thus repetitive descriptions thereof will be avoided.

### Embodiment 6

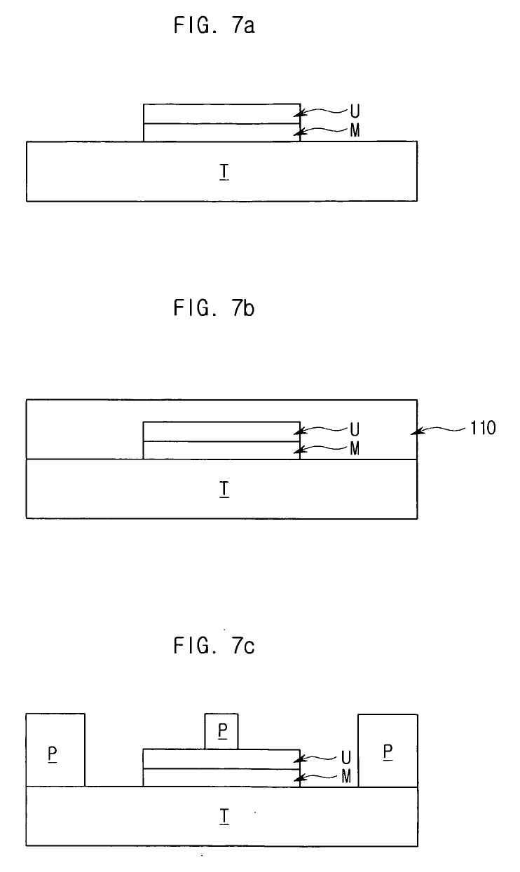

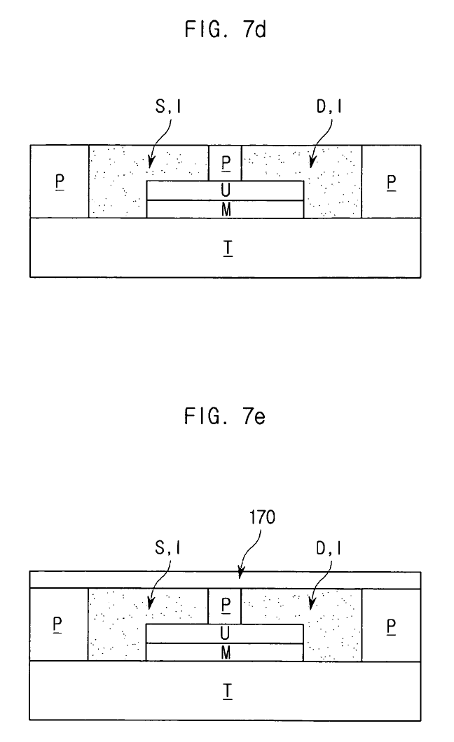

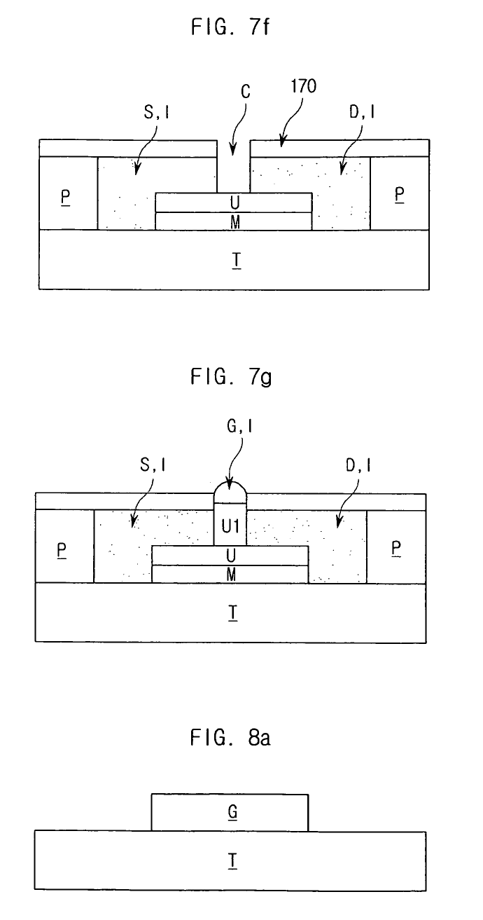

As shown in FIGS. 7a to 7g, a method S600 of fabricating a thin film transistor (TFT) in this embodiment includes a step S610 of stacking a semiconductor material M on a substrate T and stacking a dielectric material U on the semiconductor material M; a step S620 of stacking a lower layer 110 on the substrate T and the dielectric material U; a step S630 of preparing a plurality of partitions P spaced apart from each other by patterning the lower layer 110, in which at least one partition P is provided on the dielectric material U; a step S640 of filling conductive ink I used as a source electrode S and a drain electrode D of the TFT between the partition P on the dielectric material U and the neighboring partition P; a step S650 of stacking a hydrophobic insulation layer 170 having a threshold laser fluence higher than that of the partition P on the conductive ink I and the partition P; a step S660 of forming a cavity C for a gate electrode G exposing the dielectric material U by emitting a laser toward the partition P on the dielectric material U and removing the partition P on the dielectric material U and the hydrophobic insulation layer 170 stacked on the partition P on the dielectric material U; and a step S670 of filling the conductive ink I used as the gate electrode G on the dielectric material U exposed through the cavity C.

This embodiment is similar to the foregoing embodiment 5 except that the semiconductor material M and the dielectric material M are first formed on the substrate T, and therefore repetitive descriptions thereof will be avoided.

However, if the conductive ink I used for the gate electrode G is directly filled in the cavity C, it may be electrically connected to the source electrode S or the drain electrode D. Thus, an additional dielectric material U1 may be provided, and be different in permittivity from the previously stacked dielectric material U.

### Embodiment 7

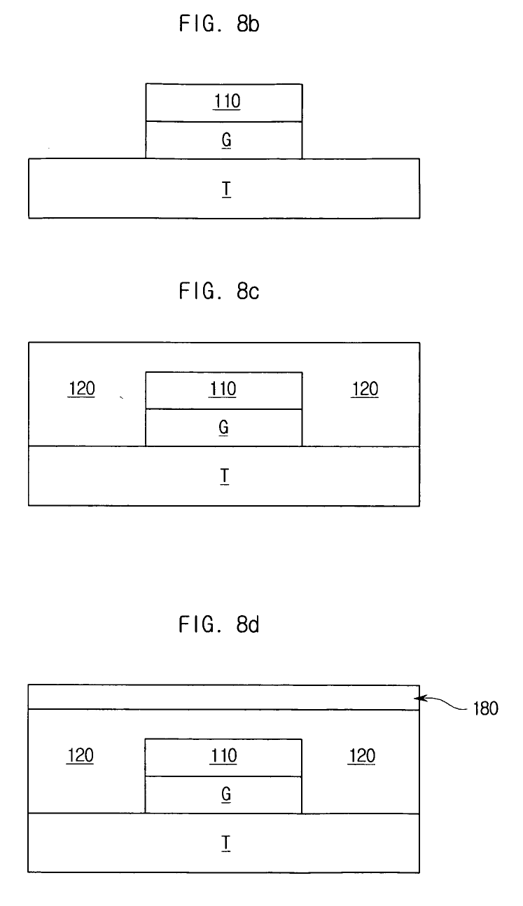

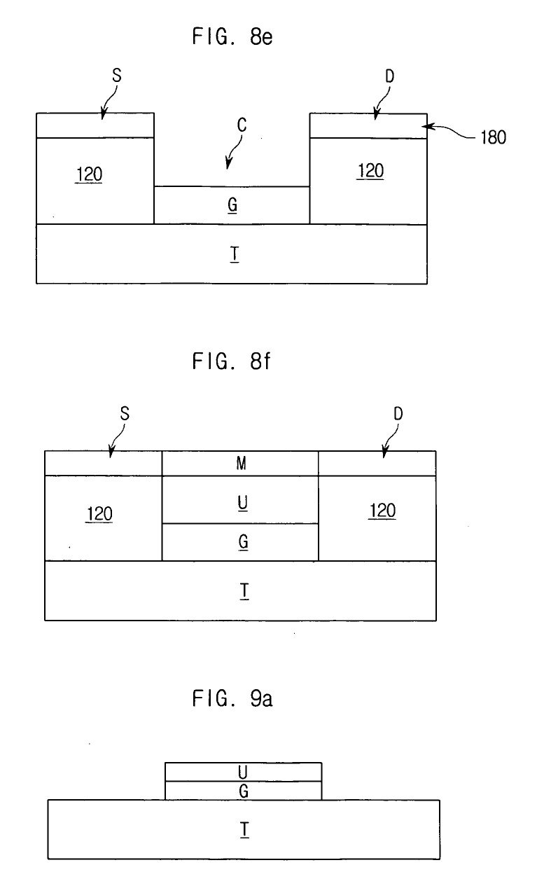

In contrast to the foregoing embodiments, as shown in FIGS. 8a to 8f, a method S700 of fabricating a thin film transistor (TFT) in this embodiment, which first stacks a gate electrode, includes a step S710 of stacking a gate electrode G on a substrate T; a step S720 of stacking a lower layer 110 on the gate electrode G; a step S730 of stacking an upper layer 120 having a threshold laser fluence higher than that of the lower layer 110 on the substrate T and the lower layer 110; a step S740 of stacking an electrode layer 180 used as a source electrode S and a drain electrode D on the upper layer 120; a step S750 of forming a cavity C for the gate electrode G by emitting a laser toward the gate electrode G and removing the lower layer 110, the upper layer 120 stacked on the lower layer 110, and the electrode layer 180 stacked above the lower layer 110; and a step S760 of filling the cavity C with a dielectric material U and a semiconductor material M.

The step S710 of stacking the gate electrode G on the substrate T and the step S720 of stacking the lower layer 110 on the gate electrode G may be achieved by the foregoing various methods.

In FIGS. 8b to 8d, the lower layer 110 is illustrated as being stacked with the same size as the gate electrode G, but this is exaggerated for describing the present embodiment. Alternatively, the lower layer 100 may be stacked to cover the left and right sides of the gate electrode G as well as the top side of the gate electrode G.

After stacking the lower layer 110, there may be provided a trimming process of trimming the shapes of the lower layer 110 and the gate electrode G by exposing the lower layer 110 and the gate electrode G to the laser.

As shown in FIG. 8e, the electrode layer 180 bisected by the cavity C have the hydrophobic properties, so that the dielectric material U and the semiconductor material M filled in the cavity C does not flow toward the electrode layer 180 but self-aligned and filled in the cavity C, thereby more precisely and easily fabricating the TFT.

To more enhance the self-aligning, an anti-wetting layer (not shown) having the hydrophobic properties may be stacked on the electrode layer 180. Further, a passivation layer (not shown) may be stacked on the anti-wetting layer, thereby protecting the TFT.

With this method, the gate electrode G and the source/drain electrodes S and D are not overlapped to thereby prevent the parasitic capacity.

The others are similar to the foregoing descriptions, and repetitive descriptions will be omitted.

### Embodiment 8

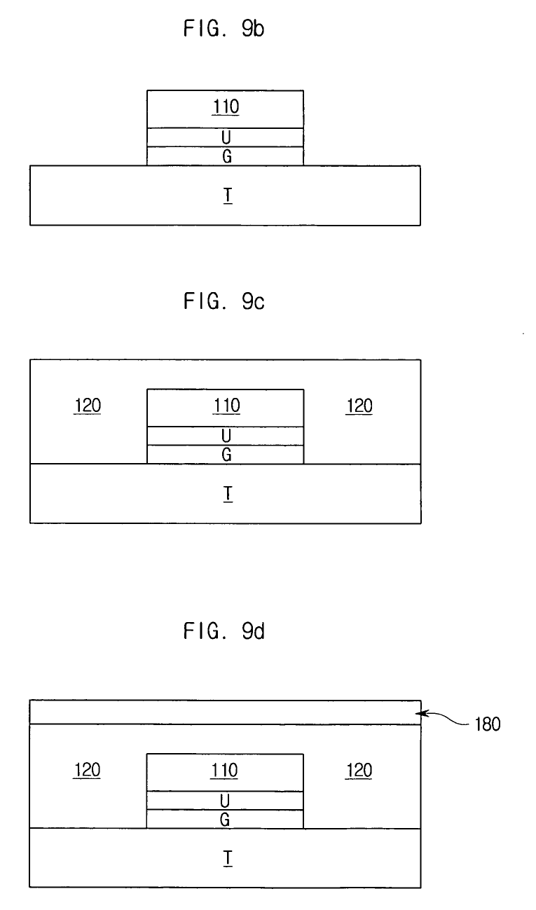

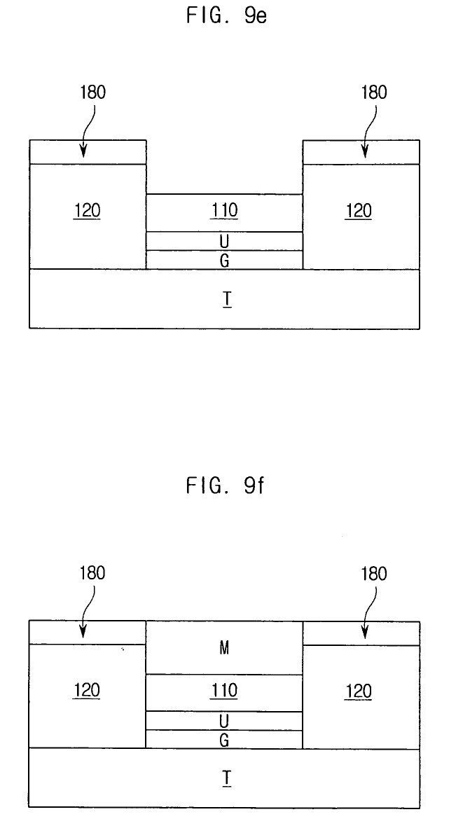

As shown in FIGS. 9a to 9f, a method S800 of fabricating a thin film transistor (TFT) in this embodiment includes a step S810 of stacking a gate electrode G on a substrate T and stacking a dielectric material U on the gate electrode G; a step S820 of stacking a lower layer 110 on the dielectric material U; a step S830 of stacking an upper layer 120 having a threshold laser fluence higher than that of the lower layer 110 on the substrate T and the lower layer 110; a step S840 of stacking an electrode layer 180 used as a source electrode S and a drain electrode D on the upper layer 120; a step S850 of forming a cavity C for the gate electrode G by emitting a laser toward the gate electrode G and removing the lower layer 110, the upper layer 120 stacked on the lower layer 110, and the electrode layer 180 stacked above the lower layer 110; and a step S860 of filling the cavity C with a semiconductor material M.

This embodiment is similar to the foregoing embodiment 7 except that the gate electrode G and the dielectric material U are first stacked on the substrate T, and thus repetitive descriptions thereof will be avoided.

As described above, when the TFT is fabricated according to the present invention, the cavity C can be precisely and easily filled by self aligning.

### Embodiment 9

The present invention uses a plurality of layers different in a threshold laser fluence so as to make a fine pattern on the principle that the layer having a low threshold laser fluence is first removed, and to fabricate a thin film transistor (TFT) using the same. It was experimentally observed that the plurality of layers are coupled to each other and decreased in the threshold laser fluence, which will be described with reference to the foregoing embodiments and FIGS. 2 to 2d.

In this embodiment, according to the fine patterning method of FIG. 2, Panipol X (Panipol INC., Finland) was used as the lower layer 110, and an organic silver layer was used as the upper layer 120. Panipol X is conductive polymer but it was processed by alkali or the like and undoped to have no conductivity, so that Panipol X can be used as only the lower layer 110.

Due to the contact between the lower layer 110 and the upper layer 120, the threshold layer fluence becomes lower. A part where the lower layer 110 and the upper layer 120 are adhered has a threshold layer fluence lower than each threshold layer fluence of the lower layer 110 and the upper layer 120, so that the part where the lower layer 110 and the upper layer 120 can be removed first.

Accordingly, only a region used as the gate cavity C is patterned as described above.

As described above, a layer having a low threshold laser fluence can be selectively removed, thereby securing an area to be filled with ink in a fine pattern region and attempting self alignment of the filled ink.

Further, semiconductor and dielectric materials are filled in a gate region between source and drain electrodes through the self alignment of ink, thereby simply and efficiently fabricating a thin film transistor (TFT) and thus reducing production costs.

Although a few embodiments of the present invention have been shown and described, it will be appreciated by those skilled in the art that changes may be made in these embodiments without departing from the principles and spirit of the invention, the scope of which is defined in the appended claims and their equivalents.

1. A method of making fine patterns by exploiting difference in threshold laser fluence of materials, the method comprising:
stacking a lower layer on a substrate;
stacking an upper layer having a threshold laser fluence higher than a threshold layer fluence of the lower layer on the lower layer and the substrate; and
forming a cavity by emitting a laser toward the lower layer and removing the lower layer and the upper layer stacked on the lower layer.

2. A method of making fine patterns by exploiting difference in threshold laser fluence of materials, the method comprising:
stacking a lower layer on a substrate;
preparing a plurality of partitions spaced apart from each other by patterning the lower layer;
stacking an upper layer having a threshold laser fluence higher than a threshold layer fluence of the lower layer on the partition and the substrate; and
forming a cavity by emitting a laser toward the partition and removing the partition and the upper layer stacked on the partition.

3. The method according to claim 1, further comprising filling the cavity with ink,
wherein the upper layer has hydrophobic properties, and a part of the substrate meeting the cavity has hydrophilic properties so that ink filled in the cavity is self aligned.

4. The method according to claim 3, wherein the upper layer has the hydrophobic properties by including a hydrophobic material, adding a hydrophobic coating layer, undergoing a plasma process or adding a hydrophobic material to the upper layer.

5. The method according to claim 1, further comprising stacking a passivation layer on the upper layer and the cavity.

6. The method according to claim 1, wherein the laser is emitted toward a top side of the substrate, or toward a bottom side of the substrate if the substrate is transparent.

7. A method of making fine patterns by exploiting difference in threshold laser fluence of materials, the method comprising:
stacking a lower layer on a substrate;
stacking a first intermediate layer having a threshold laser fluence lower than a threshold laser fluence of the lower layer on the lower layer and stacking a second intermediate layer having a threshold laser fluence higher than the threshold laser fluence of the first intermediate layer on a top side of the lower layer and lateral sides of the first intermediate layer;
stacking an upper layer having a threshold laser fluence higher than the threshold laser fluence of the first intermediate layer on the first and second intermediate layers; and
forming a cavity by emitting a laser toward the first intermediate layer and removing the first intermediate layer and the upper layer stacked on the first intermediate layer.

8. A method of fabricating a thin film transistor (TFT) by exploiting difference in threshold laser fluence of materials, the method comprising:
stacking a lower layer on a substrate;
preparing a plurality of partitions spaced apart from each other by patterning the lower layer;
filling conductive ink used as a source electrode and a drain electrode of the TFT between the partitions;
stacking a hydrophobic insulation layer having a threshold laser fluence higher than a threshold laser fluence of the partition on the conductive ink and the partition;
forming a cavity for a gate electrode by emitting a laser toward the partitions and removing the partitions and the hydrophobic insulation layer stacked on the partitions; and
filling the cavity with a semiconductor material, a dielectric material and conductive ink used as the gate electrode.

9. A method of fabricating a thin film transistor (TFT) by exploiting difference in threshold laser fluence of materials, the method comprising:
stacking a semiconductor material on a substrate;
stacking a lower layer on the substrate and the semiconductor material;
preparing a plurality of partitions spaced apart from each other by patterning the lower layer, in which at least one partition is provided on the semiconductor material;
filling conductive ink used as a source electrode and a drain electrode of the TFT between the partition on the semiconductor material and the neighboring partition;
stacking a hydrophobic insulation layer having a threshold laser fluence higher than a threshold laser fluence of the partition on the conductive ink and the partition;
forming a cavity for a gate electrode exposing the semiconductor material by emitting a laser toward the partition on the semiconductor material and removing the partition on the semiconductor material and the hydrophobic insulation layer stacked on the partition on the semiconductor material; and
filling a dielectric material and the conductive ink used as the gate electrode on the semiconductor material exposed through the cavity.

10. A method of fabricating a thin film transistor (TFT) by exploiting difference in threshold laser fluence of materials, the method comprising:
stacking a semiconductor material on a substrate and stacking a dielectric material on the semiconductor material;
stacking a lower layer on the substrate and the dielectric material;
preparing a plurality of partitions spaced apart from each other by patterning the lower layer, in which at least one partition is provided on the dielectric material;
filling conductive ink used as a source electrode and a drain electrode of the TFT between the partition on the dielectric material and the neighboring partition;
stacking a hydrophobic insulation layer having a threshold laser fluence higher than that of the partition on the conductive ink and the partition;
forming a cavity for a gate electrode exposing the dielectric material by emitting a laser toward the partition on the dielectric material and removing the partition on the dielectric material and the hydrophobic insulation layer stacked on the partition on the dielectric material; and
filling the conductive ink used as the gate electrode on the dielectric material exposed through the cavity.

11. The method according to claim 8, wherein the source electrode and the drain electrode bisected by the cavity have hydrophobic properties, so that the semiconductor material, the dielectric material and the conductive ink used as the gate electrode can be filled in the cavity as being self-aligned.

12. A method of fabricating a thin film transistor (TFT) by exploiting difference in threshold laser fluence of materials, the method comprising:
stacking a gate electrode on a substrate;
stacking a lower layer on the gate electrode;
stacking an upper layer having a threshold laser fluence higher than the threshold laser fluence of the lower layer on the substrate and the lower layer;
stacking an electrode layer used as a source electrode and a drain electrode on the upper layer;
forming a cavity for the gate electrode by emitting a laser toward the gate electrode and removing the lower layer, the upper layer stacked on the lower layer, and the electrode layer stacked above the lower layer; and
filling the cavity with a dielectric material and a semiconductor material.

13. A method of fabricating a thin film transistor (TFT) by exploiting difference in threshold laser fluence of materials, the method comprising:
stacking a gate electrode on a substrate T and stacking a dielectric material on the gate electrode;
stacking a lower layer on the dielectric material;
stacking an upper layer having a threshold laser fluence higher than that of the lower layer on the substrate and the lower layer;
stacking an electrode layer used as a source electrode and a drain electrode on the upper layer;
forming a cavity for the gate electrode by emitting a laser toward the gate electrode and removing the lower layer, the upper layer stacked on the lower layer, and the electrode layer stacked above the lower layer; and
filling the cavity with a semiconductor material.

14. The method according to claim 12, wherein the source electrode and the drain electrode bisected by the cavity have hydrophobic properties, so that the dielectric material and the semiconductor material can be filled in the cavity as being self-aligned.

15. The method according to claim 12, further comprising stacking an anti-wetting layer having hydrophobic properties on the electrode layer.

16. The method according to claim 15, further comprising stacking a passivation layer on the anti-wetting layer.
